(19) United States
(12) Patent Application Publication
(10) Pub. No.: US 2008/0303556 A1
(43) Pub. Date: Dec. 11, 2008

(54) POWER SUPPLY GROUND CROSSING DETECTION CIRCUIT

(76) Inventor: Uladzimir Fomin, Minsk (BY)

Correspondence Address: Chih Feng Yeh, 3rd Floor, No. 15, Ln. 46 , Ching-Cheng St., Song-San District, Taipei City, 10547, TW

(21) Appl. No.: 11/759,958

(22) Filed: Jun. 8, 2007

(51) Int. Cl. H03K 5/153

(52) U.S. Cl. 327/79

(57) ABSTRACT

A detecting circuit for detecting an input signal crossing a ground level is disclosed. The circuit comprises two PMOS transistors and two NMOS transistors connected, respectively. The PMOS transistors have source terminals connected to a power voltage, the gate terminals connected together and the drain terminal of the second PMOS transistors. The first NMOS transistor has the source terminal as an input terminal to retrieve an input signal, and the drain terminal to be act as output terminal and the second NMOS transistor has the source terminal grounded. The gate terminals of the two NMOS transistors are connected together and to a biased voltage. The circuit can also be used to detect the power voltage if the input terminal is set at the source terminal of the first PMOS transistor and the source terminal of the first NMOS transistor grounded.

### BACKGROUND OF THE INVENTION

1. Field of the Invention

The present invention relates to a detection circuit, and particularly, to a zero cross detection from the ground level or from the power level by a circuit including only four transistors with two current sources, and thus the current consumption of the new circuit is much low.

2. Description of the Prior Art

FIG. 1 shows a conventional zero cross detection circuit to be operated by a single power source 3, and 13 transistors. The 13 transistors formed 5 current sources. In FIG. 1, numeral 1 is an input terminal and 2 is an output terminal. The numeral 14 is a CMOS-type differential amplification circuit composed of the p-channel transistors 7, 10, and 11 and the n-channel transistors 8, and 9. The p-channel transistor 18 corresponds to a first voltage shift means as a first source follower circuit and the p-channel transistor 17 corresponds to a second voltage shift means as a second source follower circuit.

The operations of the circuit are as follows: Since the n-channel transistor 6 turned on by a power voltage 3 and pulled down voltage of the point A toward a constant voltage. Since the gate potential of the p-channel transistors 15, 7, 16, 5, and 12 are with their gates fixed to the potential of point A, the transistors 15, 7, 16, 5, and 12 are thus serviced as 5 constant current sources. The voltage at the point B is thus kept approximately constant.

The p-channel transistor 17 is a source follower and with a gate thereof grounded. It acts as a voltage shifted means to provide a function of shifted up the residual voltage at point E into a first input terminal of the CMOS type differential amplification circuit 14. The p-channel transistor 18 is a source follower and acts as a voltage shifted means too and with a gate thereof receiving an input signal to be detected from the input terminal 1. The p-channel transistor 18 has the same characteristic as the p-channel transistor 17.

Since the n-channel transistors 8, 9 formed a current mirror so that the current I_{ref} passes through the p-channel transistors 10 will be the same as the current I₀ passes through the p-channel transistors 11.

Referring to FIG. 2(A) and FIG. 2 (B) simultaneously, as an input signal L1 is higher than ground potential to be detected receiving from the input terminal 1, the potential at a second input terminal F of the CMOS type differential amplification circuit 14 is shifted up to a potential L2 by the voltage shifted up means 18. Simultaneously, a grounding potential at a first input terminal E of the CMOS type differential amplification circuit 14 is shifted up to a potential L3 by the voltage shifted up means 17. When the potential L2 is higher than the potential L3, the voltage difference between the two ends (source−gate) of PMOS transistor 11 is thus decreased. As a result, it decreases the voltage at the point C, resulted in amplifying the voltage of the output terminal 2 by n-channel transistor 13.

As an input signal L1 is lower than ground potential to be detected receiving from the input terminal 1, the potentials at the second input terminal F and the first input terminal E of the CMOS type differential amplification circuit 14 are shifted up to the potential L2, and L3 as aforementioned. However, the potential L2 is lower than the potential L3. The voltage difference between the two ends (source-drain) of PMOS transistor 10 is increased thus causing lower the voltage at point D. Consequently, the voltage difference of PMOS transistor 11 at point C is high. The potential change of ΔV2 low further causing ΔV1 high, in result, the potential at outputting terminal 2 is low, as is shown in FIG. 2B.

As an input signal L is equal to the grounding potential, At this time, the potentials at the second input terminal E and the first input terminal F of the CMOS are equal. Thus the potential at the outputting terminal 2 is indefinite. The potential of it 2 changes will be in accordance with the previous and/or latter state. For example, if the input signal L from a potential lower than ground potential rises to over the grounding potential, the potential at the outputting terminal 2 will be from a lower state changing to a higher state or if the potential of the input signal L from a potential high cross to lower than the grounding potential, the potential at the outputting terminal 2 will be from a higher state changing to a lower state. The circuit can thus provide a function the ground potential detection as the input signal cross the ground.

### SUMMARY OF THE INVENTION

An object of the present is to disclose a detecting circuit for detecting an input signal crossing a ground level or VCC power voltage. For the ground level detection is concerned, the circuit comprises two PMOS transistors placed on and connected with two NMOS transistors, respectively. The PMOS transistors have source terminals connected to a power voltage, the gate terminals connected together and the drain terminal of the second PMOS transistors. The first NMOS transistor has the source terminal as an input terminal to retrieve an input signal, and the drain terminal to be act as output terminal and the second NMOS transistor has the source terminal grounded. The gate terminals of the two NMOS transistors are connected together and to a biased voltage. The circuit can also be used to detect the power voltage if the input terminal is set at the source terminal of the first PMOS transistor and the source terminal of the first NMOS transistor grounded.

### BRIEF DESCRIPTION OF THE DRAWINGS

The present invention will be more fully understood from the detailed description, which will be given hereinafter, with the aid of the illustrations below:

FIG. 1 shows a conventional zero cross detecting circuit.

FIG. 2a and FIG. 2b show potential changes of input and output signals according to the circuit shown in FIG. 1.

FIG. 3(a) shows a zero cross detecting circuit according to a first preferred embodiment of the present invention.

FIG. 3(b) and FIG. 3(c) show potential changes of input and output signals according to the circuit shown in FIG. 3(a).

FIG. 4(a) shows a Vcc detecting circuit according to a second preferred embodiment of the present invention.

FIG. 4(b) and FIG. 4(c) show potential changes of input and output signals according to the circuit shown in FIG. 4(a).

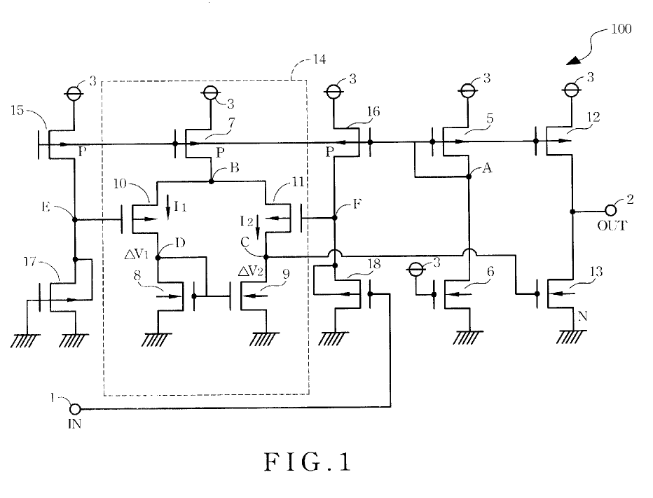

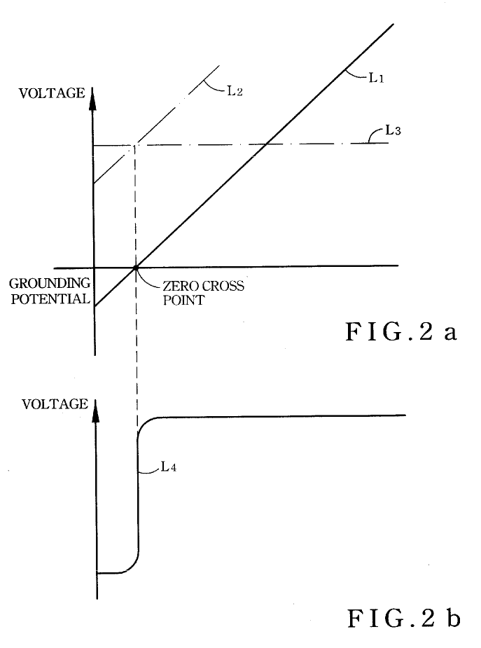

### DESCRIPTION OF THE PREFERRED EMBODIMENT

As aforementioned prior art, either a conventional zero or VCC crossing detection circuit includes 13 transistors associated with 5 current sources. Thus, the conventional detecting circuitry is much complicated and high current consumption, as a result, it is not benefit to act as an input signal cross power supply voltage detecting circuit for battery powered device.

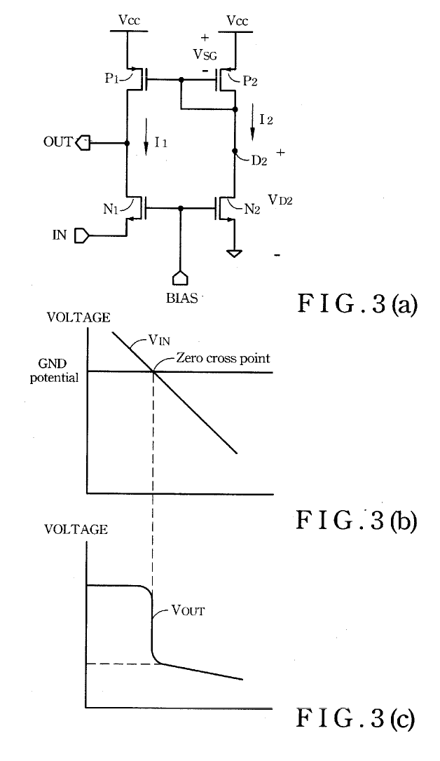

For battery powered device, a new circuit including only four transistors and two current sources according to a first preferred embodiment is thus provided to save the current consumption, as shown in FIG. 3(a). In FIG. 3(a), it shows an input signal crossing ground detecting circuit detection circuit consisting of two PMOS transistors P1, P2 and two NMOS transistors N1, N2.

In circuit, the PMOS transistors P1, P2 are with their source terminals connected to a power VCC, gate terminals connected together, and with individual drain terminals, respectively, connected to the drain terminals of the NMOS transistor N1 and the NMOS transistor N2. The gate terminal of the PMOS transistor P2 is further connected to the drain terminal of itself. The gate terminals of the NMOS transistors N1, N2 are connected to a bias signal BIAS. The source terminal of the NMOS transistor N2 is grounded but the source terminal of the NMOS transistor N1 is coupled with an input signal IN. The drain terminal of the NMOS transistor N1 is further provided as an output terminal OUT.

The operations of the zero cross detected circuit are depicted as follows. Please referring to FIG. 3 (b) and (c) simultaneously. When a voltage of the input signal V_{IN} is higher than ground (GND) level or just floating and a voltage V_{BIAS}, which is higher than the threshold voltage V_{tN2} (i.e., V_{BIAS}−V_{tN2}>0) of the NMOS transistor N2, applies on the gate of the NMOS transistors N2, N1, the NMOS transistor N2 is turned ON and put into triode mode but the NMOS transistor N1 is turned OFF, due to the fact that V_{BIAS}−V_{tN1}−V_{IN}<0. Thus I₂ is generated but 11=0. No current flowing through the PMOS transistor P1, results in pulling up the voltage of the OUT terminal up to VCC.

As the voltage of the input signal V_{IN} is decreasing to close to the ground (GND) level (>0+), so that the sum of the (V_{BIAS}−V_{tN1}−V_{IN}) is slightly greater than 0 and the current I₁ starts to flow i.e., I₁≠0 but still less than I2. In the situation, V_{D2}<VCC−V_{SG}+abs(Vₜₚ₂) where abs(Vtp2), V_{SG} are, respectively, an absolute value of the threshold voltage, and voltage of the source to the gate of the PMOS transistor P2. The PMOS transistors P1, P2 will be put into a saturation mode. As a result, the voltage V_{OUT} of the outputting terminal OUT is still pulled up and is close to VCC.

As the voltage of the input signal V_{IN} equals to ground, the circuit becomes a current mirror. Thus I₂=I₁. The voltage V_{OUT} of the outputting terminal OUT takes an intermediate level between VCC and GND.

As the voltage of the input signal V_{IN} is lower than the ground level, in the situation, I₁>I₂, and the Vᵢₙ₀ and V_{BIAS} will then put the NMOS transistor N1 into saturation mode. The voltage V_{OUT} of the outputting terminal OUT is kept at low.

Accordingly, the voltage V_{OUT} of the outputting terminal OUT will switch from high to low, or from low to high, input signal V_{IN} crossing grounding level willed be detect.

Aforementioned embodiment is based on size of the NMOS transistor N1 the same as the NMOS transistor N2. It is also possible to adjust the margin of zero crossing detection voltage to make it little less or little more than zero if the size ratio of the NMOS transistor N1 to the NMOS transistor N2 is not equal to 1.

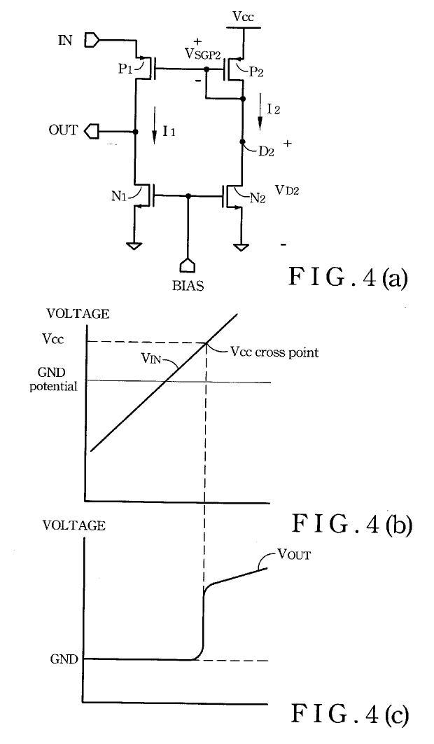

The aforementioned circuit can be modified so as to detect an input signal IN crossing VCC level, as is shown in FIG. 4 (a). Basically, the numbers, types of the transistors and the connection relationships are the same as is shown in FIG. 3(a) except the position of the input terminal IN. In FIG. 4, a second preferred embodiment of the present invention, the input terminal IN is set at the source terminal of the PMOS transistor p1. The detailed operation of the input signal IN crossing VCC detection circuit is depicted as follows.

In FIG. 4, when a voltage of an input signal IN is grounded or lower than the ground level (GND), a voltage V_{BIAS} higher than the threshold voltage V_{tN2} of the NMOS transistor N2 applies on the gate of the NMOS transistors N2 and N1, the NMOS transistor N2 is turned ON because of V_{BIAS}−V_{tN2}>0 and put it into a triode mode and the voltage V_{D2}<VCC−V_{SGP2}+ abs(Vₜₚ₂). A constant current I₂ flows through the NMOS transistor N2 to ground. No current flows through the PMOS transistor P1 (I₁=0). The voltage of the OUT is kept low.

As the voltage of the input signal IN rises from the grounding potential but still lower than VCC, the current I₁ starts to flow through the NMOS transistor N1 to ground. The voltage V_{BIAS} and the current I₁ put the NMOS transistor N1 into triode mode but since I₁<<I₂. Thus the voltage of the output terminal OUT will still be kept low.

When the voltage of the input signal IN becomes equal to VCC, The circuit becomes a current mirror having a mirror current I₁ through the PMOS P1 equals to the reference I₂ through the PMOS P2. The voltage of the output terminal OUT is pulled up to VCC. And thus the input signal IN crossing VCC level is detected, please refer to FIGS. 4(b) and 4(c), the input signal changed and output signal changed.

The benefits of the invention:
1. The current consumption is anticipated to be low comparing to the prior art since the circuit according to the present invention is composed of four transistors only. Consequently, it is particularly apt to use in those probable device.
2. The margin or zero cross detection voltage can be make it little less or little more than zero just by change the ratio of the channel width over channel length (W/L)_{N1}/(W/L)_{N2}, of the transistors.

As is understood by a person skilled in the art, the foregoing preferred embodiment of the present invention is an illustration, rather than a limiting description, of the present invention. It is intended to cover various modifications and similar arrangements included within the spirit and scope of the appended claims, the scope of which should be accorded the broadest interpretation so as to encompass all such modifications and similar structures.

What is claimed is:

1. A detecting circuit for detecting an input signal crossing a specified voltage, comprising:
a first PMOS transistor, a second PMOS transistor, a first NMOS transistor, and a second NMOS transistor, wherein both of said first PMOS transistor and second PMOS transistor have their gate terminals connected to both of drain terminals of said second PMOS transistor and second NMOS transistor, and said first NMOS transistor and said second NMOS transistor have their gate terminals connected to a BIAS voltage, and a source terminal of said second NMOS transistor is grounded and a source terminal of said second PMOS transistor is connected to a power voltage, and both of drain terminals of said first PMOS transistor and first NMOS transistor are connected and acted as an output terminal; and
when said specified voltage is a ground level, then a source terminal of said first NMOS transistor is connected to said input signal and a source terminal of said first PMOS transistor is connected to said power voltage;
when said specified voltage is said power voltage, then said source terminal of said first NMOS transistor is grounded and a source terminal of said first PMOS transistor is connected to said input signal.

2. The detecting circuit according to claim 1 wherein said specified voltage can be adjusted a little more or less than said ground level according to a size ratio of said second NMOS transistor over said first NMOS transistor.

3. The detecting circuit according to claim 1 wherein said specified voltage can be adjusted a little more or less than said power voltage according to a size ratio of said second PMOS transistor over said first PMOS transistor.

4. A detecting circuit for detecting an input signal crossing a ground level, comprising:
a first PMOS transistor having a source terminal connected to a power voltage;
a second PMOS transistor having a source terminal connected to said power voltage, a gate terminal connected to a drain terminal of itself and a gate terminal of said first PMOS transistor;
a first NMOS transistor having a drain terminal connected to said drain terminal of said first PMOS transistor and a source terminal provided for an input signal to input; and
a second NMOS transistor having a source terminal grounded, a drain terminal connected to said drain terminal of said second PMOS transistor, and a gate terminal connected to a gate terminal of said first NMOS transistor and a bias voltage.

5. The detecting circuit according to claim 4 wherein said ground level can be adjusted to a little more or less according to a size ratio of said second NMOS transistor over said first NMOS transistor.

6. A detecting circuit for detecting an input signal crossing a power voltage, comprising:
a first PMOS transistor having a source terminal connected to a power voltage;
a second PMOS transistor having a source terminal connected to said power voltage, a gate terminal connected to a drain terminal of itself and a gate terminal of said first PMOS transistor; and
a first NMOS transistor having a drain terminal connected to said drain terminal of said first PMOS transistor and a source terminal grounded; and
a second NMOS transistor having a source terminal provided for an input signal to input, a drain terminal connected to said drain terminal of said second PMOS transistor, and a gate terminal connected to a gate terminal of said first NMOS transistor and a bias voltage.

7. The detecting circuit according to claim 6 wherein said power voltage detected can be adjusted to a little more or less according to a size ratio of said second PMOS transistor over said first PMOS transistor.
